(19) United States
(12) Patent Application Publication
(10) Pub. No.: US 2026/0342038 A1
(43) Pub. Date: Oct. 29, 2026

(54) OPTICAL DEVICE AND METHOD OF MANUFACTURING OPTICAL DEVICE

(71) Applicant: FURUKAWA ELECTRIC CO., LTD., Tokyo (JP)

(72) Inventors: Taketsugu SAWAMURA, Tokyo (JP); Kazuhiko KASHIMA, Tokyo (JP); Kyoko NAGAI, Tokyo (JP); Nitidet THUDSALINGKARNSAKUL, Phranakorn Sri Ayutthaya (TH); Rattanaporn SUKSOMBOON, Phranakorn Sri Ayutthaya (TH); Noppawan CHONGKAMNUNG, Phranakorn Sri Ayutthaya (TH)

(73) Assignee: FURUKAWA ELECTRIC CO., LTD., Tokyo (JP)

(21) Appl. No.: 19/703,187

(22) Filed: Jun. 10, 2026

Related U.S. Application Data
(63) Continuation of application No. PCT/JP2023/044484, filed on Dec. 12, 2023.

(51) Int. Cl. H01S 5/02251; H01S 5/02315

(52) U.S. Cl. CPC H01S 5/02251; H01S 5/02315

(57) ABSTRACT

An optical device includes: a plurality of subassemblies each including a laser emitting element, an optical fiber to which output light from the laser emitting element is coupled and a submount on which the laser emitting element and the optical fiber are mounted; and a base on which the plurality of subassemblies are mounted.

### CROSS-REFERENCE TO RELATED APPLICATIONS

This application is a continuation of International Application No. PCT/JP 2023/044484, filed on Dec. 12, 2023, the entire contents of which are incorporated herein by reference.

### BACKGROUND

The present disclosure relates to an optical device and a method of manufacturing the optical device.

A known optical device includes a laser emitting element and an optical fiber, to which output light from the laser emitting element is coupled (for example, Japanese Unexamined Patent Application Publication No. 2004-349294). An optical device disclosed in Japanese Unexamined Patent Application Publication No. 2004-349294 includes only a single combination of a laser emitting element and an optical fiber.

### SUMMARY

In recent years, for example, optical devices each including a plurality of combinations each being a combination of a laser emitting element and an optical fiber have been developed for use in data centers.

Inventors of the present application have made intensive studies on configurations of and manufacturing methods for such optical devices, and have found that various problems may arise when all of a plurality of laser emitting elements and optical fibers are directly mounted on a common member. Such problems include, for example, that, in each combination, adjustment of positions of a laser emitting element and an optical fiber for increasing coupling efficiency requires time, thereby prolonging the time required for manufacturing an optical device, and that the size of the optical device increases for interference to be avoided, the interference being between the components and a jig for performing the position adjustment.

There is a need for an improved and novel optical device and a method of manufacturing the optical device that enable, for example, mitigation or avoidance of problems associated with providing a plurality of combinations each being a combination of a laser emitting element and an optical fiber.

According to one aspect of the present disclosure, there is provided an optical device including: a plurality of subassemblies each including: a laser emitting element; an optical fiber to which output light from the laser emitting element is coupled; and a submount on which the laser emitting element and the optical fiber are mounted; and a base on which the plurality of subassemblies are mounted.

According to another aspect of the present disclosure, there is provided a method of manufacturing an optical device including: making a plurality of subassemblies each including a laser emitting element, an optical fiber to which output light from the laser emitting element is coupled; and a submount on which the laser emitting element and the optical fiber are mounted; and mounting the plurality of subassemblies on a base.

### BRIEF DESCRIPTION OF THE DRAWINGS

FIG. 1 is an exemplary and schematic perspective view of a communication device including an optical device of a first embodiment;

FIG. 2 is an exemplary and schematic perspective view of an internal configuration of the optical device of the first embodiment;

FIG. 3 is an exemplary and schematic plan view of the internal configuration of the optical device of the first embodiment;

FIG. 4 is an exemplary and schematic perspective view of a cross section taken along a line IV-IV in FIG. 3;

FIG. 5 is an exemplary and schematic plan view of part of a subassembly included in the optical device of the first embodiment;

FIG. 6 is a flowchart illustrating an example of a procedure of a method of manufacturing the optical device of the first embodiment;

FIG. 7 is an exemplary front view of part of an array of optical fibers at an end portion of a connector of the optical device of the first embodiment;

FIG. 8 is an exemplary and schematic perspective view of a cross section of an optical device of a second embodiment, the cross section being at a position equivalent to that in FIG. 4; and

FIG. 9 is an exemplary and schematic perspective view of a cross section of an optical device of a third embodiment, the cross section being at a position equivalent to that in FIG. 4.

### DETAILED DESCRIPTION

Exemplary embodiments will be disclosed hereinafter. Configurations of the embodiments and functions and results (effects) brought about by these configurations described hereinafter are just examples. The present disclosure may be implemented by configurations other than those disclosed hereinafter with respect to the embodiments. Furthermore, the present disclosure achieves at least one of various effects (including derivative effects) achieved by these configurations.

The embodiments described hereinafter include like components. Therefore, the configurations of the embodiments achieve like functions and effects based on the like components. Furthermore, the same reference sign will hereinafter be assigned to such like components and any redundant description thereof may be omitted.

Ordinals are assigned for convenience to distinguish between directions, members, and portions in this specification and do not indicate any priority or order.

In each drawing, an X direction is represented by an arrow X, a Y direction by an arrow Y, and a Z direction by an arrow Z. The X direction, Y direction, and Z direction intersect one another and are orthogonal to one another. Furthermore, the X direction may be referred to as a longitudinal direction or an extending direction, the Y direction may be referred to as a transverse direction or a width direction, and the Z direction may be referred to as a thickness direction or a height direction.

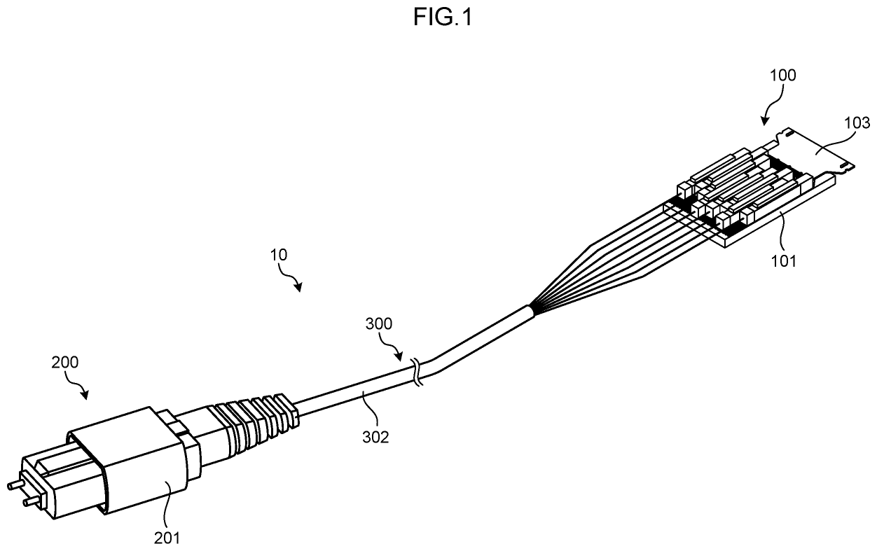

FIG. 1 is a perspective view of a communication device 10 of a first embodiment. As illustrated in FIG. 1, the communication device 10 includes an optical module 100, a connector module 200, and an optical fiber cable 300. The communication device 10 may also be referred to as an optical communication device.

The optical fiber cable 300 includes a plurality of optical fibers 301, and a tube 302 that bundles and surrounds the plurality of optical fibers 301. The plurality of optical fibers 301 extend between the interior of the optical module 100 and the interior of the connector module 200.

The connector module 200 has a connector body 201. The plurality of optical fibers 301 are fixed to the connector body 201 via, for example, an adhesive.

The optical module 100 has a base 101, and a flexible printed circuit (FPC) 103. FIG. 1 illustrates only part of the optical module 100. The optical module 100 includes a printed circuit board assembly (PCBA) connected to the FPC 103, a controller mounted on the PCBA, a power source unit, an outer boot that covers a connection portion between the optical fibers 301 and the optical module 100, and an outer casing (neither of which are illustrated in the drawings). The optical module 100 is an example of an optical device.

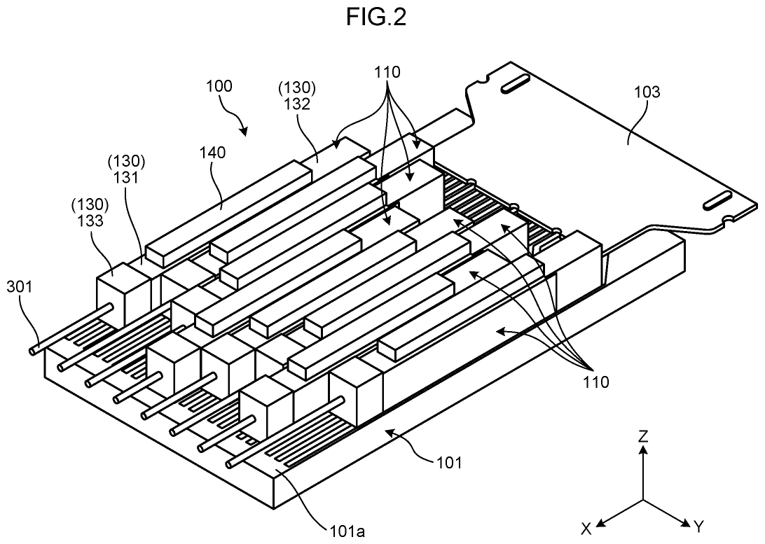

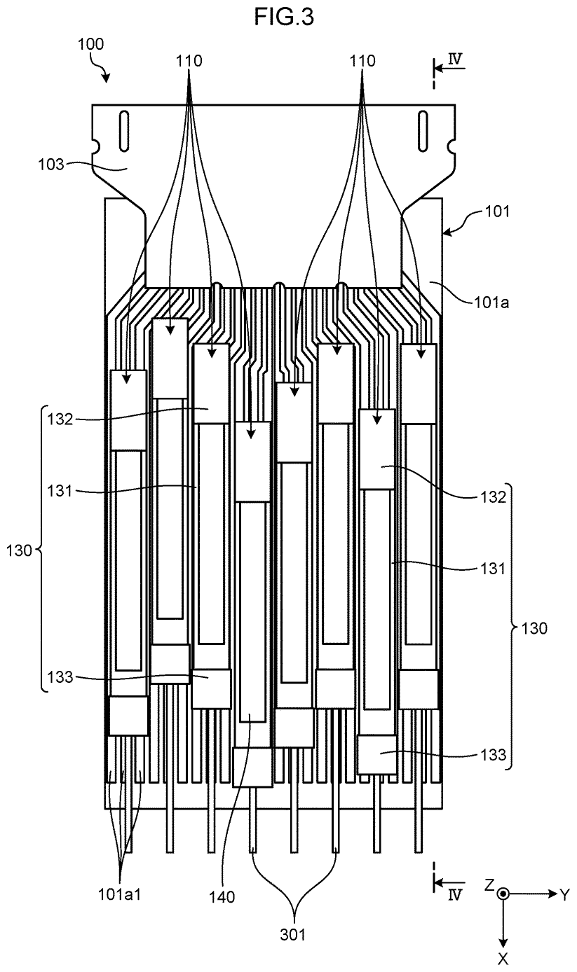

FIG. 2 and FIG. 3 are diagrams illustrating an internal configuration of the part of the optical module 100, the part being illustrated in FIG. 1, FIG. 2 is a perspective view of this part, and FIG. 3 is a plan view of the part.

As illustrated in FIG. 2 and FIG. 3, the optical module 100 has a plurality of subassemblies 110, in addition to the base 101 and the FPC 103. The plurality of subassemblies 110 are accommodated in a space (accommodation chamber) surrounded by the base 101 and an outer cover not illustrated in the drawings. That is, the base 101 and the outer cover form a housing of the optical module 100.

The base 101 has a rectangular and plate-like shape, has a substantially constant thickness in the Z direction, and extends so as to intersect and be orthogonal to the Z direction. Furthermore, the base 101 has a surface 101a. The surface 101a, at an end portion in the Z direction, faces the Z direction and extends so as to intersect and be orthogonal to the Z direction.

The plurality of subassemblies 110 are mounted on the surface 101a with, for example, a bonding material (not illustrated in the drawings), such as an adhesive or solder. For transferring heat generated in the subassemblies 110 to the base 101, the bonding material preferably has thermal conductivity higher than at least thermal conductivity of gas surrounding the subassemblies 110 and the base 101. For example, the bonding material may contain a filler made of a substance having relatively high thermal conductivity.

The subassemblies 110 each have a substantially constant width in the Y direction and a substantially constant height in the Z direction and extend in the X direction. The optical fibers 301 extend respectively from the subassemblies 110. In the optical module 100, the number of the subassemblies 110 and the number of the optical fibers 301 are the same. The plurality of optical fibers 301 extend substantially along the X direction over the surface 101a of the base 101. Furthermore, the plurality of optical fibers 301 are arranged in the Y direction with substantially regular intervals therebetween. The X direction is an example of a first direction and the Y direction is an example of a second direction.

Furthermore, as illustrated in FIG. 2 and FIG. 3, in this embodiment, the positions at which the plurality of subassemblies 110 are mounted on the base 101 in the X direction are nonuniform. That is, in this embodiment, lengths of the optical fibers 301 between the connector module 200 and the subassemblies 110 do not need to be made strictly uniform.

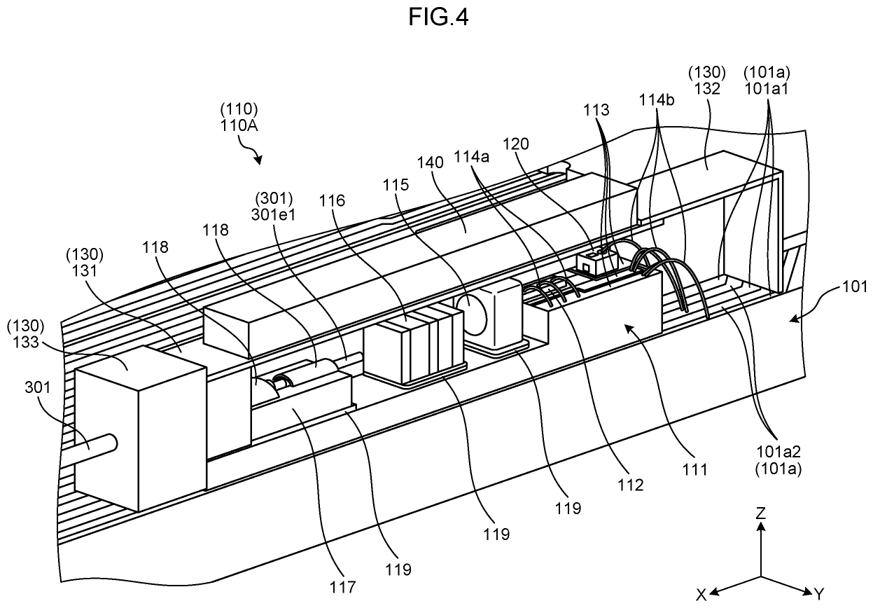

FIG. 4 is a perspective view of a cross section taken along a line IV-IV in FIG. 3. As illustrated in FIG. 4, a subassembly 110A (110) has a submount 111, a laser emitting element 112, a lens 115, an isolator 116, a support member 117 that supports the optical fiber 301, and a photodiode 120.

The laser emitting element 112 is, for example, a semiconductor laser element. Electrodes 113 are provided on the submount 111. The laser emitting element 112 and the electrodes 113 are electrically connected via wires 114a made of a conductor. Furthermore, a plurality of wiring patterns 101a1 made of a conductor and insulating regions 101a2 between the wiring patterns 101a1 are provided on the surface 101a of the base 101. The electrodes 113 and the wiring patterns 101a1 are electrically connected via wires 114b made of a conductor. Furthermore, the wiring patterns 101a1 are electrically connected to a wiring pattern (not illustrated in the drawings) provided on the FPC 103, and the wiring pattern on the FPC 103 is electrically connected to a power source (not illustrated in the drawings). In this configuration, the laser emitting element 112 emits light in response to supply of electric power from the power source via the wiring pattern on the FPC 103, the wiring patterns 101a1 on the surface 101a of the base 101, the wires 114b, the electrodes 113, and the wires 114a. The wiring patterns 101a1 are an example of wiring portions.

Laser light (output light) output from the laser emitting element 112 is transmitted to an end portion 301e1 of the optical fiber 301 via the lens 115 and the isolator 116 and coupled to the end portion 301e1. The lens 115 and the isolator 116 are an example of optical components. Any optical component other than the lens 115 and the isolator 116 may be provided between the laser emitting element 112 and the optical fiber 301. Furthermore, without provision of the lens 115, the optical fiber 301 may be configured as a lensed fiber. In this case, the isolator 116 may be not provided.

The photodiode 120 detects intensity of output light from the laser emitting element 112. An intensity signal detected by the photodiode 120 is transmitted to the controller via the wires 114b, the wiring patterns 101a1, and the wiring pattern on the FPC 103.

The optical fiber 301 is mounted on the support member 117 via an adhesive not illustrated in the figure. Furthermore, an adhesive 118 that fixes the optical fiber 301 to the support member 117 is provided around the optical fiber 301 on the support member 117.

The submount 111 extends in the X direction with a substantially constant width in the Y direction. The submount 111 has a height in the Z direction that changes according to its position in the X direction. That is, the submount 111 is provided with a step. The submount 111 is made of, for example, a ceramic (material) having relatively high thermal conductivity, such as aluminum nitride. Furthermore, the submount 111 may be configured as, for example, a silicon optical bench (SiOB).

The laser emitting element 112, the lens 115, the isolator 116, and the support member 117 are mounted on the submount 111 via an adhesive 119. The optical fiber 301 is mounted on the support member 117 via an adhesive (not illustrated in the figure). That is, the optical fiber 301 is mounted on the submount 111 via the support member 117, for example. Furthermore, the laser emitting element 112 and the photodiode 120 are mounted on the submount 111 via solder, for example. The adhesive and solder are examples of a bonding material.

The subassemblies 110 each have a cover 130. The cover 130 covers components of the subassembly 110, the components being other than the cover 130, such as the laser emitting element 112, the lens 115, the isolator 116, part of the optical fiber 301, the part including the end portion 301e1, the photodiode 120, and the wires 114a and 114b. Furthermore, the cover 130 is mounted on the submount 111.

As illustrated in FIG. 2 to FIG. 4, the cover 130 has a plurality of members, specifically, a first member 131, a second member 132, and a boot 133. The first member 131 covers the laser emitting element 112, the lens 115, the isolator 116, the optical fiber 301, the wires 114a, and the photodiode 120, on the surface 101a of the base 101. Openings are provided at end portions of the first member 131, the end portions being in the X direction and a direction opposite to the X direction. The second member 132 covers the opening at the end portion of the first member 131 and the wires 114b, the end portion being in the X direction. The boot 133 closes the opening at the end portion of the first member 131, the end portion being in the direction opposite to the X direction. The optical fiber 301 passes through the boot 133. This configuration enables the wires 114b and the wiring patterns 101a1 to be bonded together while preventing a bonding device (not illustrated in the figure) from interfering with the cover 130 in a state where the first member 131 and the boot 133 have been mounted on the submount 111 and the second member 132 has not been mounted on the submount 111, for example. If the cover 130 were composed of a single member, at least during bonding operation, the entire cover 130 would have to be removed from the submount 111, exposing the components, which might compromise the protection of the components. In this regard, according to the embodiment, the bonding operation is able to be performed in a state where the first member 131 and the boot 133 have been mounted on the submount 111 to cover the components while the second member 132 has not been mounted on the submount 111 and the wires 114a have been exposed, and smooth bonding between the wires 114b and the wiring patterns 101a1 is thus enabled while avoiding interference of the bonding device with the cover 130 in the state where the components have been protected. Furthermore, having the first member 131 and the boot 133 as separate members enables the boot 133 to be formed of, for example, an elastic material softer and more flexible than the first member 131. As a result, higher sealing in the gap between the boot 133 and the optical fiber 301 is able to be achieved, while higher protection of the components is able to be provided by the first member 131, which is more rigid than the boot 133. The first member 131 and the boot 133 are an example of a first cover, and the second member 132 is an example of a second cover. By providing a resin material having a relatively low elastic modulus instead of the second member 132 and the boot 133, the openings at the two end portions of the first member 131 may be sealed. In this case, this resin material is an example of the second cover.

Furthermore, at least part of the cover 130 is made of a material having thermal conductivity higher than at least that of gas (for example, air or an inert gas) surrounding the laser emitting element 112 and the submount 111 so that the part serves as a heat transfer path (heat dissipation path) for heat generated by the laser emitting element 112, which is a heat generating element, and at least part of the cover 130 is thermally connected to the submount 111 and the laser emitting element 112. Specifically, for example, the first member 131 and the second member 132 are made of a metallic material having relatively high thermal conductivity, such as an aluminum-based material including pure aluminum or an aluminum alloy, or a copper-based material including oxygen-free copper or a copper alloy. For example, the first member 131 is attached to the submount 111 by a bonding material or a fastener, and the second member 132 is attached to the first member 131 or the submount 111 by a bonding material or a fastener. The submount 111 is thermally connected to the laser emitting element 112. The first member 131 is thermally connected to the submount 111 and thus thermally connected to the laser emitting element 112. The second member 132 is thermally connected to the first member 131 or the submount 111 and thus thermally connected to the laser emitting element 112.

A thermally conductive sheet 140 is interposed between the cover 130 and the outer cover. The thermally conductive sheet 140 is made of a material softer than those of the cover 130 and the outer cover, the material having flexibility and elasticity, and is in close contact with both the cover 130 and the outer cover. The outer cover is also made of a material having thermal conductivity higher than at least that of gas surrounding the laser emitting element 112 and the submount 111, and specifically is made of a metallic material having relatively high thermal conductivity, such as an aluminum-based material including pure aluminum or an aluminum alloy, or a copper-based material including oxygen-free copper or a copper alloy. Accordingly, heat generated in the laser emitting element 112 is transferred to the outer cover via the cover 130 and the thermally conductive sheet 140 and is released from the outer cover. Therefore, according to the embodiment, the improved heat dissipation from the subassembly 110 reduces temperature increases in the laser emitting element 112 and other components, and it thus becomes less difficult for desired optical characteristics and reliability to be obtained. The thermally conductive sheet 140 is an example of a heat transfer member. The outer cover may be provided with a heat dissipating structure, such as a heat sink including a plurality of fins or a plurality of pins.

At least part of the cover 130, or in the embodiment, the entirety of the cover 130, that is, the first member 131, the second member 132, and the boot 133, is made of a material having light blocking properties with respect to output light from the laser emitting element 112. Leakage of unnecessary light (stray light) to the outside of the subassembly 110 is thereby able to be reduced.

As illustrated in FIG. 3 and FIG. 4, the wiring patterns 101a1 extend in the X direction on the surface 101a of the base 101. Therefore, as illustrated in FIG. 4, within a predetermined range where the wiring patterns 101a1 extend, the wires 114b are able to be bonded to any positions on the wiring patterns 101a1. Therefore, within the predetermined range where the wiring patterns 101a1 extend, electrical connection between the wiring patterns 101a1 and the laser emitting element 112 or photodiode 120 by means of the wires 114b having a predetermined length is able to be achieved relatively easily, irrespective of the position of the subassembly 110 in the X-direction.

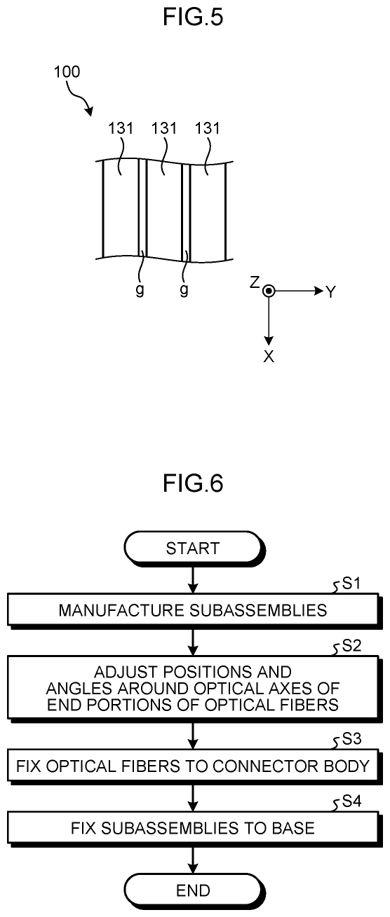

FIG. 5 is a plan view of part of the optical module 100 and is a diagram illustrating only the first members 131 of the covers 130. As illustrated in FIG. 5, the first members 131 that are adjacent to each other in the Y direction and hence the subassemblies 110 are spaced apart from each other with a gap g therebetween without being in contact with each other. Transfer of heat generated in the laser emitting element 112 to the laser emitting element 112 and other components included in the other subassembly 110 different from the subassembly 110 having that laser emitting element 112 is thereby minimized and it thus becomes less difficult for desired optical characteristics and reliability to be achieved in the laser emitting element 112 and other components included in the other subassembly 110. A heat insulating material having thermal conductivity lower than that of gas that is present around the first members 131 and the submounts 111 may be interposed between the two first members 131, that is, the two subassemblies 110.

FIG. 6 is a flowchart illustrating an example of a manufacturing procedure for the optical module 100. A manufacturing procedure for a case where the optical fibers 301 are polarization maintaining optical fibers will be described herein as an example.

As illustrated in FIG. 6, firstly, the subassemblies 110 are manufactured (S1). At S1, each of the subassemblies 110 described above (see FIG. 2 to FIG. 4, but the subassemblies 110 are not mounted on the base 101 yet) is manufactured. In this manufacture, to obtain required coupling efficiency for light output from the laser emitting element 112 with respect to the end portion 301e1 of the optical fiber 301, the fixed position of the optical fiber 301 with respect to the support member 117 and the fixed position of the lens 115 with respect to the submount 111, for example, are adjusted for each of the subassemblies 110. In the case where the optical fibers 301 are polarization maintaining optical fibers, rotational angles of the optical fibers 301 around their optical axes (center axes) are also adjusted. Specifically, for example, the angle around the optical axis of the end portion 301e1 of the optical fiber 301 is adjusted so that the direction in which the tensile stress is applied in the cross section substantially coincides with the slow-axis direction of the laser light. S1 is an example of a first process.

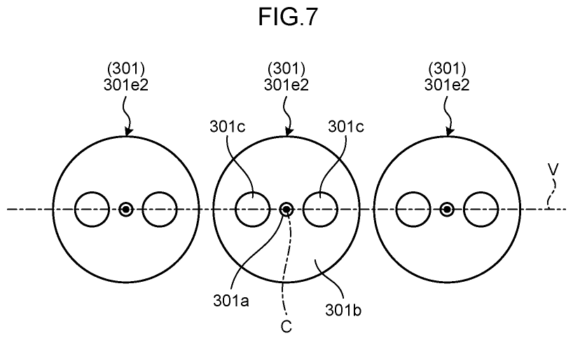

Subsequently, positions and angles around central axes C of end portions 301e2 of the optical fibers 301 fixed to the connector body 201 (see FIG. 1) are adjusted (S2). FIG. 7 is a front view of a desired arrayed state of the end portions 301e2 of the optical fibers 301 fixed to the connector body 201. As illustrated in FIG. 7, the optical fibers 301 each have a core 301a, cladding 301b, and two stress applying members 301c. The core 301a extends along the central axis C (optical axis). The two stress applying members 301c are arranged such that the midpoint between the two stress applying members 301c substantially coincides with the central axis C. Furthermore, the cladding 301b is arranged to surround the core 301a and the two stress applying members 301c. At S2, as illustrated in FIG. 7, the positions and rotational angles around the central axes C of the end portions 301e2 of the plurality of optical fibers 301 are adjusted so that the central axes C, the cores 301a, and the stress applying members 301c of the plurality of optical fibers 301 are arranged substantially along an array direction V of the plurality of optical fibers 301 and the central axes C are arranged at predetermined intervals, for example, at equal intervals. S2 is an example of a fourth process.

Subsequently, while maintaining the positions and angles illustrated in FIG. 7, the end portions 301e2 of the plurality of optical fibers 301 are fixed to the connector body 201 via, for example, a bonding material, such as an adhesive (S3). S3 is an example of a third process.

At S3, after the end portions 301e2 of the plurality of optical fibers 301 have been fixed firmly to the connector body 201, the plurality of subassemblies 110 are mounted on the base 101 (S4). In the embodiment, executing Step S4 following Step S3 after Step S1 thus results in nonuniform mounting positions of the plurality of subassemblies 110 on the base 101 in the X direction, as illustrated in FIG. 2 in a case where lengths of the optical fibers 301 of the plurality of subassemblies 110 are different from one another. S4 is an example of a second process.

Furthermore, if S3 were to be executed after S4, then after adjustment to the state illustrated in FIG. 7 at S3, twisting torque of the subassemblies 110 and the optical fibers 301 could be transmitted to the end portions 301e2 before the bonding material hardens, and the end portions 301e2 could thus twist relative to the connector body 201, and the state illustrated in FIG. 7 might be unable to be maintained. In this regard, in this embodiment, as described above, Step S4 is executed after Step S3 and the end portions 301e2 are thus able to be fixed to the connector body 201 at the positions and angles that have been adjusted as illustrated in FIG. 7. Consequently, unwanted rotation of the polarization plane of output light to an optical component (referred to as an “external optical component”), such as an optical fiber (not illustrated in the drawings) connected to the connector module 200 or an unwanted decrease in the coupling efficiency of the output light to the external optical component is able to be reduced.

Through intensive studies by the inventors, it was found that, if all of the plurality of laser emitting elements 112, optical components, such as the lens 115 and the isolator 116, and the optical fibers 301 were directly mounted on a common base 101, various problems could arise. These problems include, for example: that for individual combinations of the laser emitting elements 112, the optical components, and the optical fibers 301, adjusting the positions of the laser emitting elements 112, the optical components, and the optical fibers 301 to improve the coupling efficiency takes time, thereby prolonging the time required for manufacturing a single optical module 100; and that the size of the optical module 100 is increased for avoiding interference between the components and the jig for performing the position adjustment.

In this regard, according to the embodiment, at S1, the subassemblies 110 each having the combination of the laser emitting element 112, the optical components, and the optical fiber 301 are manufactured, and thereafter at S4, the subassemblies 110 are fixed to the base 101. As a result, advantages, such as reductions in the effort and cost required for manufacturing the optical module 100, and minimization of an increase in the size of the optical module 100, are able to be obtained.

Furthermore, the above described configuration and manufacturing method enable constraints to be alleviated, the constraints being on the lengths of the optical fibers 301 fixed to the plurality of subassemblies 110 in the embodiment. The lengths of the optical fibers 301 fixed to the respective subassemblies 110 are prone to vary according to, for example: variations in the cutting positions in the process of cutting the end portions; and adjustments of the relative positions within the subassemblies 110 to improve the coupling efficiency. If the fixed positions of the end portions 301e1 of the optical fibers 301 with respect to the base 101 were constrained in the optical module 100 having the plurality of laser emitting elements 112 and the optical fibers 301 corresponding to the laser emitting elements 112: the cutting process would be carried out carefully in order to equalize the lengths of the optical fibers 301, thereby requiring effort and time in the cutting process; the yield of the optical fibers 301 could decrease; relatively long optical fibers 301 incorporated in the optical module 100 might be bent; and stress might be generated as a result of such bending. In this regard, according to the embodiment, some nonuniformity (differences or variations) in the mounting positions of the plurality of subassemblies 110 on the base 101 in the X direction is permissible. As a result, constraints on the lengths of the optical fibers 301 fixed to the respective subassemblies 110 are able to be alleviated, thereby providing advantages, such as reductions in manufacturing effort and cost, and avoidance of a decrease in the yield of the optical fibers 301.

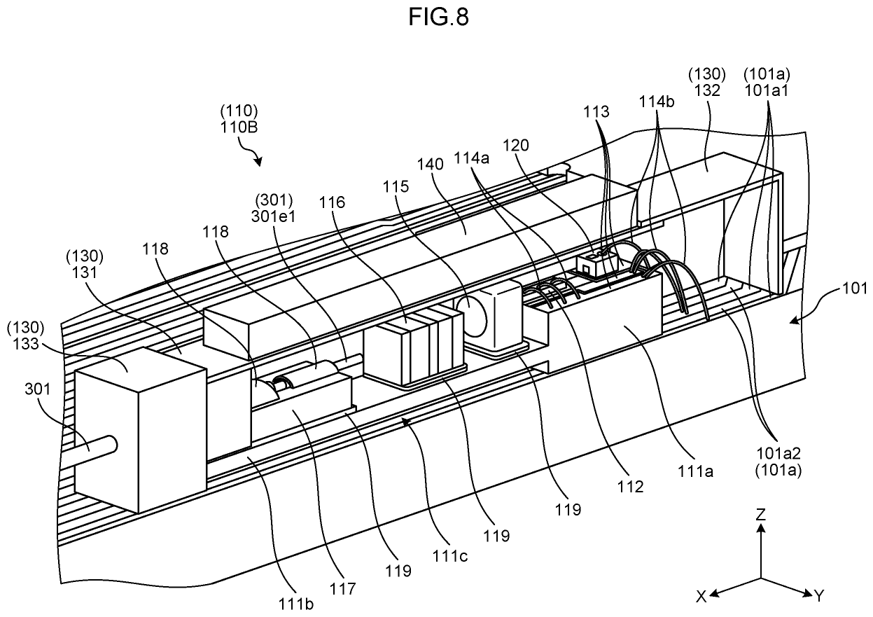

FIG. 8 is a perspective view of a cross section of a subassembly 110B (110) of a second embodiment, the cross section being at a position equivalent to that in FIG. 4. As illustrated in FIG. 8, in this embodiment, a submount 111 has a first part 111a and a second part 111b. The first part 111a is adjacent to a laser emitting element 112 and is connected to a base 101. The first part 111a and the base 101 are connected to each other by a bonding material, such as solder or an adhesive. Furthermore, the second part 111b is spaced from the base 101, extends substantially along the X direction from the first part 111a, and supports optical components, such as a lens 115 and an isolator 116, as well as an optical fiber 301. A gap 111c has been provided between the second part 111b and the base 101.

This embodiment enables an area to be reduced, the area being an area over which the submount 111 and the base 101 are connected to each other. Therefore, for example, an advantage is able to be provided, the advantage being that even when a difference between coefficients of thermal expansion of the submount 111 and the base 101 is relatively large, distortion or deformation of the submount 111 due to temperature changes is able to be minimized. Furthermore, because the first part 111a is adjacent to the laser emitting element 112, which is a heat generating element, heat generated in the laser emitting element 112 is able to be transferred to the base 101 via the first part 111a. That is, this configuration also achieves the required level of heat dissipation by means of the submount 111. The second part 111b may just support at least the optical fiber 301, and the optical components may be supported by the first part 111a.

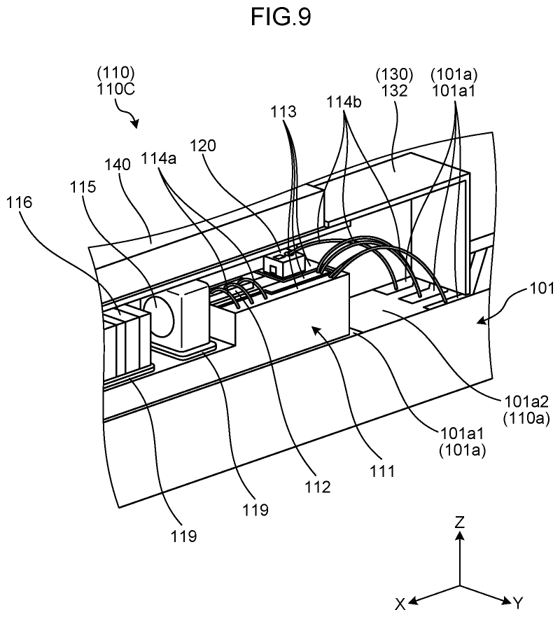

FIG. 9 is a perspective view of a cross section of a subassembly 110C (110) of a third embodiment, the cross section being at a position equivalent to that in FIG. 4. As illustrated in FIG. 9, in this embodiment, wiring patterns 101a1 do not extend as far in the X direction as in the first embodiment or second embodiment. As a result, in this embodiment, to accommodate nonuniformity in the positions of the subassemblies 110 (submounts 111) in the X direction as illustrated in FIG. 2 and FIG. 3, in all of the subassemblies 110, the electrical connection between the wiring patterns 101a1 and the electrodes 113 on the submount 111, that is, the conductors in the subassembly 110, is achieved by increasing the lengths of the wires 114b as the submount 111 is located further away from the wiring patterns 101a1 in the X direction. In this case, an optical module 100 includes a plurality of wires 114b having different lengths, and more specifically, a plurality of wires 114b whose lengths increase with increasing distance between wiring patterns 101a1 and a submount 111 in the X direction. In this embodiment, the length of a second member 132 of a cover 130 in the X direction also increases as the distance between the wiring patterns 101a1 and the submount 111 in the X direction and the lengths of the wires 114b increase.

The embodiments have been described above by way of example, but the embodiments are just example and are not intended to limit the scope of the disclosure. The above described embodiments may be implemented in various other forms, and various omissions, substitutions, combinations, and modifications can be made without departing from the spirit of the disclosure. In addition, specifications (such as structures, types, directions, models, sizes, lengths, widths, thicknesses, heights, numbers, arrangements, positions, and materials) of the components and shapes may be changed as appropriate.

For example, the first cover for each subassembly is not essential, and a first cover covering a plurality of subassemblies may be provided.

The present disclosure enables obtainment of a new and improved optical device and a method of manufacturing the optical device.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical device comprising:
a plurality of subassemblies each including:
a laser emitting element;
an optical fiber to which output light from the laser emitting element is coupled; and
a submount on which the laser emitting element and the optical fiber are mounted; and
a base on which the plurality of subassemblies are mounted.

2. The optical device according to claim 1, further comprising:
a cable including
a plurality of optical fibers extending from the plurality of subassemblies, and
a tube surrounding the plurality of optical fibers; and
a connector to which end portions of the plurality of optical fibers are fixed.

3. The optical device according to claim 1, wherein the respective optical fibers of the plurality of subassemblies extend substantially along a first direction and are arranged with intervals therebetween in a second direction intersecting the first direction, on the base.

4. The optical device according to claim 3, wherein positions of the plurality of subassemblies in the first direction on the base are nonuniform.

5. The optical device according to claim 3, further comprising two subassemblies that are adjacent to each other in the second direction with a gap therebetween, the two subassemblies being two adjacent ones of the plurality of subassemblies.

6. The optical device according to claim 1, further comprising a first cover configured to cover at least the laser emitting element, the first cover having light blocking properties.

7. The optical device according to claim 6, wherein the first cover has thermal conductivity higher than that of gas surrounding the laser emitting element.

8. The optical device according to claim 7, wherein the first cover is thermally connected to the submount.

9. The optical device according to claim 1, further comprising a housing configured to accommodate the plurality of subassemblies.

10. The optical device according to claim 3, wherein
the plurality of subassemblies are fixed onto a surface of the base,
the surface includes, provided thereon, a wiring portion made of a conductor, and
the wiring portion and a conductor in the plurality of subassemblies are electrically connected via a wire made of a conductor.

11. The optical device according to claim 10, wherein the wiring portion includes a part extending substantially along the first direction on the surface.

12. The optical device according to claim 10, wherein the wire includes a plurality wires having different lengths.

13. The optical device according to claim 10, further comprising a second cover configured to cover the wire.

14. The optical device according to claim 1, wherein
the laser emitting element is configured to output the output light in a first direction, and
the submount includes:
a first part that is adjacent to the laser emitting element and is connected to the base; and
a second part that is spaced from the base, extends from the first part, and supports at least the optical fiber.

15. The optical device according to claim 1, wherein the submount and the base have thermal conductivity higher than that of gas surrounding the laser emitting element.

16. The optical device according to claim 1, wherein the optical fiber is a polarization maintaining optical fiber.

17. A method of manufacturing an optical device, the method comprising:
making a plurality of subassemblies each including a laser emitting element, an optical fiber to which output light from the laser emitting element is coupled; and a submount on which the laser emitting element and the optical fiber are mounted; and
mounting the plurality of subassemblies on a base.

18. The method of manufacturing the optical device, according to claim 17, further comprising fixing end portions of a plurality of optical fibers to a connector body after the first process and before the mounting, the plurality of optical fibers including the optical fibers extending from the plurality of subassemblies.

19. The method of manufacturing the optical device, according to claim 18, wherein
the plurality of optical fibers are polarization maintaining optical fibers, and
the method further comprises adjusting angles of the end portions around central axes of the end portions with respect to the connector body between the making and the fixing.
